(19) United States
(12) Patent Application Publication
(10) Pub. No.: US 2020/0207066 A1
(43) Pub. Date: Jul. 2, 2020

(54) FLEXIBLE BARRIER MEMBRANE AND METHOD FOR PRODUCING THE FLEXIBLE BARRIER MEMBRANE

(71) Applicants: Marc Grimmé, PALAISEAU (FR); Pascal Dubuis, CLERLANDE (FR); Malys-Claire Koun, ORSAY (FR); Stéphane Marais, MALAUNAY (FR); Aracelys Maria Marcano Zerpa, ROUEN (FR); Kateryna Fatyeyeva, HOUPPEVILLE (FR); Fabienne Poncin-Épaillard, LE MANS (FR)

(72) Inventors: Marc Grimmé, PALAISEAU (FR); Pascal Dubuis, CLERLANDE (FR); Malys-Claire Koun, ORSAY (FR); Stéphane Marais, MALAUNAY (FR); Aracelys Maria Marcano Zerpa, ROUEN (FR); Kateryna Fatyeyeva, HOUPPEVILLE (FR); Fabienne Poncin-Épaillard, LE MANS (FR)

(73) Assignee: CARMAT, Vélizy-Villacoublay (FR)

(21) Appl. No.: 16/631,269

(22) PCT Filed: Jun. 26, 2018
(86) PCT No.: PCT/FR2018/051562

§ 371 Date: Jan. 15, 2020

(30) Foreign Application Priority Data
Jul. 19, 2017 (FR) 1756847

(51) Int. Cl. B32B 27/08; B32B 27/40; B32B 27/30; B32B 37/24; C23C 16/50; C23C 16/40

(52) U.S. Cl. CPC B32B 27/08; B32B 2307/546; B32B 27/306; B32B 27/304; B32B 37/24; C23C 16/50; C23C 16/401; B32B 2255/20; B32B 2255/24; B32B 2255/10; B32B 2307/7244; B32B 2307/7246; B32B 2307/7265; B32B 2310/0409; B32B 2375/00; B32B 2329/04; B32B 2327/00; B32B 2535/00; B32B 27/40

(57) ABSTRACT

The invention relates to a flexible barrier membrane (1) comprising at least one first layer (2a) of polyurethane, and at least one second layer (20) of material(s), which is incorporated into the first layer (2a) of polyurethane by a modification of at least one surface of the at least one layer of polyurethane. The at least one material of the at least one second layer is selected from the materials including inorganic silicon oxide, organic silicon oxide and a barrier polymer. The invention also relates to a method for producing the flexible barrier membrane (1).

### TECHNICAL FIELD

The present invention relates to, generally, the field of materials having properties which are barriers to fluids and to gases. More specifically, it relates to a flexible membrane having barrier properties.

### STATE OF THE ART

Polyurethanes are polymers which play a major role in the development of numerous devices in various fields, for example, in the textiles, construction field, or medical devices going from catheters to prostheses (artificial heart). There is a growing interest for using polyurethanes for medical devices, due to the increased and adjustable mechanical properties thereof, the ease of treatment thereof, and mainly the good biocompatibility thereof. However, as with most polymers, they are known to be easily permeable to water and to gas, because of the amorphous rubbery state thereof. The permeability to gases (and in particular, to dioxygen) and to water of the material is a significant factor, since the entry of air through a polyurethane membrane in a prosthesis would be conveyed by a loss of effectiveness. Furthermore, the entry of water through the membrane can lead to the corrosion of metal parts which are incorporated into the prosthesis.

For these reasons, it is essential to use a material having enhanced barrier properties. The barrier properties of a material correspond to the capacity of the material to slow down or to prevent the passage of gases or fluids (liquids) through itself under the effect of a gradient.

In a non-limiting manner, the gradient can be a pressure gradient, a concentration gradient and/or a temperature gradient. The greater the barrier properties are, the more the gas or the fluid is slowed down during the passage thereof through the material. In the state of the art, there are different approaches to increasing the barrier properties of the polyurethanes to gas and to water. These ways of increasing can be split into two large families: the volume modification of the polyurethane or the surface treatment of the polyurethane.

In the case of volume modification, there is the way of mixing polymers which makes it possible to easily control the gas transfer properties of by adjusting the composition and polymer microstructure ratio constituting the mixture. The modification by mixing polymers forms the subject of a particular interest on the part of manufacturers, both for the simplicity of implementation, and for the stability between the phases, different from multilayer systems which are sometimes the cause of delamination phenomena. The way of mixing also makes it possible to develop more efficient materials. However, it is only applicable when the polymers selected are miscible or have a sufficient compatibility together.

Another way of volume modification consists of the incorporation of nanoparticles in the polyurethane matrix to form a nanocomposite. Nanocomposites are materials which result from the incorporation of nanostructures or nanofillers in an organic polymer matrix. Contrary to usual composites where the dispersed fillers are of micrometric size, this incorporation of nanofillers leads to an increase of interfaces and specific interactions leading to a high modification of the overall material properties. This approach to improve the barrier properties of the materials has been proven to be promising. The improvement of the barrier properties is generally attributed to an increase of tortuosity. In the case of nanocomposites, the nanofillers being considered as impermeable, the path for diffusing small molecules is extended which leads to a decrease in the permeability of the material. This effect is all the more significant whether the nanofillers are lamellar or spherical structures and if possible, oriented perpendicularly to the diffusion path. From the industrial standpoint, the interest in these nanocomposite materials is based on the low cost of clays from which the nanofillers come, the ease of implementation by usual methods (injection-blasting, extrusion, etc.), and the significant improvement of the functional properties. However, for biomedical applications, the biocompatibility of the fillers added to the polyurethane matrix and the absence of risk of migrations of nanofillers to the surface of the material by elution effect must be ensured.

In the case of the surface treatment, an approach described in the state of the art to improve the barrier properties consists of applying on the polymer substrate, coatings making it possible to reduce the overall permeability of the treated materials. This method makes it possible to combine the properties of each of the deposited layers. There are numerous commercial examples of multilayer materials, in particular for food packaging applications. Further to the techniques consisting of producing sandwiched structures, it is also possible to deposit outer or inner layers on the polymer making it possible to improve the barrier properties thereof.

Given the physico-chemical and biological constraints imposed by the biomedical use of polyurethane-based membranes, in particular cardiac prostheses, these techniques do not appear to be the most suitable to improve the barrier properties of polyurethane both to the gases (to dioxygen, in particular) and to water without altering the properties thereof and the biocompatibility of it, and this with the concern of modifying the shape of the complex geometry material (irregular, three-dimensional shape).

### SUMMARY OF THE INVENTION

The present invention aims to overcome these disadvantages by proposing a flexible membrane having properties which are barriers to water and to dioxygen.

To this end, the invention relates to a flexible barrier membrane.

According to the invention, the flexible barrier membrane comprises:
at least one first layer of polyurethane, and
at least one second layer of material(s) which is/are incorporated into the first layer of polyurethane by a modification of at least one surface of the layer or layers of polyurethane, the material or materials of the second layer or layers being comprised from materials comprising inorganic silicon oxide, organic silicon oxide of chemical formula SiOₓC_{z}H_{w} and a barrier polymer.

Thus, the membrane such as described above benefits from properties which are a barrier to water and to dioxygen brought by the layer of material(s) obtained by the modification of at least one surface of the layer of polyurethane.

In addition, the barrier polymer is comprised from among the following polymers: poly(vinyl alcohol-co-ethylene) (EVOH), polyvinylidene chloride (PVDC), polyisobutylene (PIB).

Moreover, advantageously, the layer or layers of material(s) are sandwiched between two layers of polyurethane.

The invention also relates to a method for producing a flexible barrier membrane.

According to the invention, the method comprises the following steps:
a step of preparing a layer of polyurethane;
a step of modifying at least one surface of the layer of polyurethane such that the surface or surfaces of the layer of polyurethane form at least one layer of materials, the material or materials being comprised from materials comprising a barrier polymer, inorganic silicon oxide and organic silicon oxide of chemical formula SiOₓC_{z}H_{w}.

Furthermore, the barrier polymer is comprised from among the following polymers: EVOH, PVDC and PIB.

According to a first embodiment, the modification step comprises a modification by casting-evaporation including the following sub-steps:
a sub-step of casting a poly(vinyl acetate-co-ethylene) (EVA) solution on at least one surface of the layer of polyurethane, the casting sub-step making it possible to deposit a layer of EVA on the layer of polyurethane;
a sub-step of hydrolysing the layer of EVA to obtain a layer of EVOH.

According to a second embodiment, the modification step comprises a modification by jet of sprayed solution including the following sub-steps:
a sub-step of preparing a solution containing at least one barrier polymer;
a sub-step of projection, consisting of projecting said solution on at least one surface of the layer of polyurethane;
a sub-step of drying, to form a layer comprising at least one barrier polymer.

According to a first variant of a third embodiment, the modification step comprises a first modification by plasma-enhanced chemical vapour deposition including the following sub-steps:
a sub-step of implementing the layer of polyurethane in a vacuumed air environment;
a sub-step of introducing a silicon oxide precursor in gaseous form in the vacuumed air environment, such that the precursor is distributed homogenously in the vacuumed air environment;
a sub-step of exposing the layer of polyurethane to the precursor in order to form a layer comprising inorganic silicon oxide.

According to a second variant of the third embodiment, the modification step comprises a second modification by plasma-enhanced chemical vapour deposition including the following sub-steps:
a sub-step of implementing the layer of polyurethane in a vacuumed air environment;
a sub-step of introducing dioxygen and a silicon oxide precursor in gaseous form in the vacuumed air environment, such that the dioxygen and the precursor is distributed homogenously in the vacuumed air environment;
a sub-step of exposing the layer of polyurethane to dioxygen and to the precursor in order to form a layer comprising organic silicon oxide.

In addition, the silicon oxide precursor comprises an organosilicon precursor in gaseous form.

As an example, the organosilicon precursor is comprised from among the following precursors: tetramethylsilane (TMS), tetraethyloxisilane, hexamethyldisiloxane, hexamethyldisilazane, tetraethylsilane, tetramethyldisilazane, tetramethyl orthosilicate and tetramethylcyclotetrasiloxane.

According to a variant, the silicon oxide precursor comprises a hydrocarbon precursor.

As an example, the hydrocarbon precursor corresponds to acetylene.

Moreover, the method further comprises a step of depositing at least one second layer of polyurethane on the layer or layers of materials such that the layer or layers of materials are sandwiched between the two layers of polyurethane.

### BRIEF DESCRIPTION OF THE FIGURES

The invention, with the features and advantages thereof, will emerge more clearly upon reading the description made in reference to the appended drawings, wherein:

FIG. 1 represents an embodiment of the flexible barrier membrane obtained from a modification of the layer of polyurethane by casting-evaporation,

FIG. 2 represents another embodiment of the flexible barrier membrane obtained from a modification of the layer of polyurethane by casting-evaporation,

FIG. 3 represents an embodiment of the flexible barrier membrane obtained from a modification of the layer of polyurethane by plasma-enhanced chemical vapour deposition,

FIGS. 4 to 6 represent an embodiment of the flexible barrier membrane obtained from a modification of the layer of polyurethane by jet of EVOH solution sprayed at different EVOH grades,

FIG. 7 represents an embodiment of the flexible barrier membrane obtained from a modification of the layer of polyurethane by jet of sprayed PVDC solution,

FIG. 8 represents an embodiment of the flexible barrier membrane obtained from a modification of the polyurethane layer by jet of sprayed PIB solution,

FIG. 9 represents an embodiment of the flexible barrier membrane, wherein the layers of material are comprised between two layers of polyurethane, each of the layers of material being obtained by modification of the layers of polyurethane by jet of PVDC and EVOH solution,

FIG. 10 represents an embodiment of the flexible barrier membrane, wherein the layer of material is comprised between two layers of polyurethane, the layer of material being obtained by a modification of the layers of polyurethane by jet of PVDC solution,

FIG. 11 represents an embodiment of the flexible barrier membrane, wherein the layers of material are comprised between two layers of polyurethane, each of the layers of material being obtained by modification of the layers of polyurethane by jet of PVDC and PIB solution,

FIG. 12 represents an embodiment of the flexible barrier membrane, wherein the layers of material are comprised between two layers of polyurethane, one of the layers of material being obtained by modification by jet of PVDC solution, the other layers being obtained by modification by plasma-enhanced chemical vapour deposition,

FIG. 13 schematically represents the main steps of the method for producing the flexible barrier membrane.

### DETAILED DESCRIPTION

Below, the description will make reference to the figures cited above.

The invention relates to a flexible barrier membrane 1.

Said flexible barrier membrane 1 comprises at least one first layer 2a of polyurethane.

For a biomedical application, polyurethane forming the flexible barrier membrane 1 can be any type of polyurethane having the required mechanical properties, biostability and biocompatibility. As an example, polyurethane corresponds to a polycarbonate-urethane or a polycarbonate-urethane-urea. These polyurethanes can also be known, respectively, under the commercial names, “Bionate® II”, of the company DSM Polymer Technology Group and “Chronoflex® AR-LT” of the company AdvanSource Biomaterial. Polyurethane can also be obtained by synthesis.

The flexible barrier membrane 1 also comprises at least one second layer 20 of material or materials (hereinafter, material(s)). The second layer 20 of material(s) is incorporated into the first layer 2a of polyurethane by a modification of at least one surface of the layer or layers 2a of polyurethane.

The material or materials of the second layer or layers 20 is/are comprised from materials comprising inorganic silicon oxide, organic silicon oxide and a barrier polymer.

The barrier polymer means that this is a polymer which has physical, chemical or physicochemical properties which contribute to reducing the passage of gas or water through said barrier polymer.

The barrier polymer can be a synthesised or commercially obtained polymer.

The barrier polymer can be a polymer comprised from among the following polymers: poly(vinyl alcohol-co-ethylene) (EVOH), polyvinylidene chloride (PVDC), polyisobutylene (PIB).

FIGS. 4 to 6 represent a flexible barrier membrane 1 comprising a layer 2a of polyurethane and a layer 7, 8, 9 of EVOH.

FIG. 7 represents a flexible barrier membrane 1 comprising a layer 2a of polyurethane and a layer 10 of PVDC.

FIG. 8 represents a flexible barrier membrane 1 comprising a layer 2a of polyurethane and a layer 11 of PIB.

For example, EVOH and PIB come from the company Sigma Aldrich and PVDC from the company Goodfellow Cambridge Limited.

It is possible to use different EVOH grades. For example, an EVOH with 27% of ethylene groups (EVOH27), an EVOH with 32% of ethylene groups (EVOH32) or an EVOH with 44% of ethylene groups (EVOH44).

FIG. 4 represents a flexible barrier membrane 1 comprising a layer 2a of polyurethane and a layer 7 of EVOH27.

FIG. 5 represents a flexible barrier membrane 1 comprising a layer 2a of polyurethane and a layer 8 of EVOH32.

FIG. 6 represents a flexible barrier membrane 1 comprising a layer 2a of polyurethane and a layer 9 of EVOH44.

Inorganic silicon oxide has, as a chemical formula: SiOₓ, wherein the parameter x of inorganic silicon oxide represents the ratio between the quantity of oxygen and the quantity of silicon. In a non-limiting manner, the parameter x is between 1.5 and 2.2, preferably between 1.8 and 2.1.

Organic silicon oxide has, as a chemical formula: SiOₓC_{z}H_{w}. In a non-limiting manner, the parameter x of organic silicon oxide is between 1 and 2.4, the parameter z being between 0.2 and 2.4, the parameter w being between 0.05 and 4.

According to an embodiment, the layer or layers 20 of material(s) are sandwiched between two layers 2a and 2b of polyurethane.

The flexible barrier membrane 1 is produced by a method comprising the following steps (FIG. 13):
a step E1 of preparing a layer 2a of polyurethane;
a step E2 of modifying at least one surface of the layer 1 of polyurethane such that the surface or surfaces of the layer 2a of polyurethane form at least one layer 20 of materials, the material or materials being comprised from among materials comprising inorganic silicon oxide, organic silicon oxide and a barrier polymer.

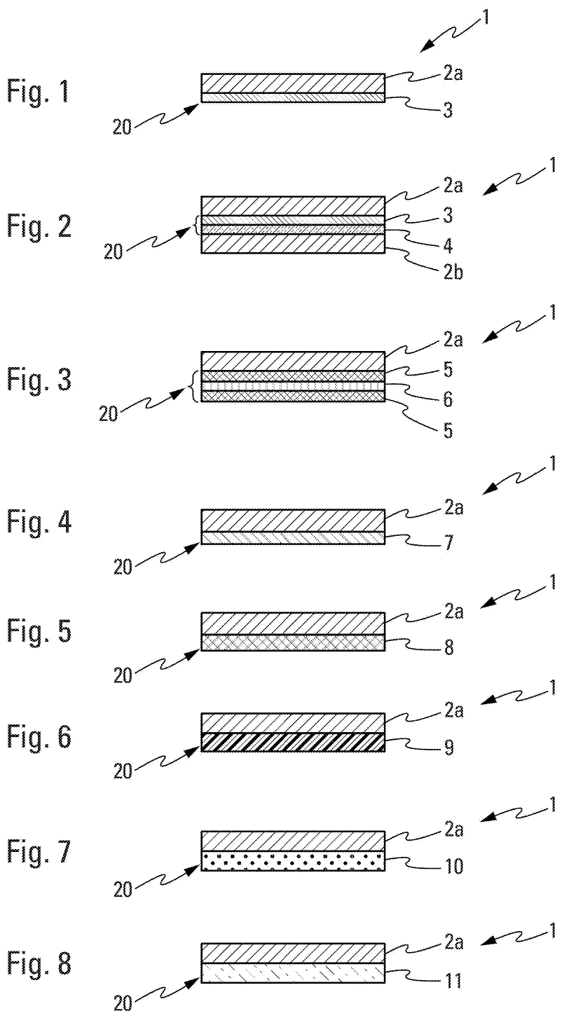

According to a first embodiment (FIGS. 1 and 2), the step E2 of modifying comprises a modification by casting-evaporation in order to obtain a layer of EVOH.

The modification step thus comprises a sub-step of casting a poly(vinyl acetate-co-ethylene) (EVA) solution on at least one surface of the layer 2 of polyurethane. This casting sub-step makes it possible to deposit a layer of EVA 4 on the layer of polyurethane.

The EVA used is, for example, a copolymer at 70% by mass of vinyl acetate also known under the name of Levapren® 700 of the company Lanxess Co., of which the molar mass Mw is substantially equal to 268,000 g/mol.

The EVA solution has been prepared from at least one of the following solvents: chloroform, dichloromethane, dimethylacetamide (DMAc) and dimethylformamide (DMF).

The modification step E2 also comprises a sub-step of hydrolysing the layer of EVA 4 after evaporation of the solvent or solvents to obtain a layer of EVOH 3. The hydrolysis corresponds to a surface hydrolysis of the EVA using a base solution (NaOH, for example) and in the presence of water. The thickness of the hydrolysed layer 3 varies according to the treatment time (FIGS. 1 and 2).

According to a second embodiment (FIGS. 4 to 12), the modification step E2 comprises a modification by jet of sprayed solution.

The modification step E2 thus comprises a sub-step of preparing a solution containing at least one barrier polymer included from the materials comprising EVOH, PVDC, PIB. The solution is prepared from at least one of the barrier polymers and one solvent.

The modification step E2 comprises a sub-step of projection, consisting of projecting said solution over at least one surface of the layer 2a of polyurethane.

The barrier polymer concentration in the solution is such that the solution is sufficiently fluid for the good functioning of an air brush making it possible for the jet of sprayed solution and to obtain homogenous and uniform layers. For example, the air brush is an air brush of the model Fengda® BD-134K. The air brush makes it possible to spray the solution in aerosol form continuously and homogenously over the surface to be modified. For example, the solution contains between 3% and 20% by mass of barrier polymer to be sprayed over the surface(s) of the layer 2a of polyurethane using an air brush. For this, a predetermined quantity of polymer has been dissolved in the DMAc while stirring, in order to form a homogenous solution (10% m/m for EVOHs of different grades and 20% m/m for PVDC). In the case of PIB, m-xylene (or meta-xylene) has been used as a solvent (3% m/m). Then, the solution has been poured into the beaker of the air brush to then be sprayed, with a maximum horizontal and vertical pressure, at the surface of the surface or surfaces of the layer 2a of polyurethane cleaned beforehand with compressed air to remove dust. The coating has been produced in single-layer or multilayer form.

The modification step comprises a drying sub-step to form a layer 4, 5, 6, 7, 8 which comprises at least one barrier polymer. In a non-limiting manner, the drying lasts for around ten minutes.

The projection sub-step and the drying sub-step can be carried out several times with different barrier polymers. When all the layers 20 are produced by these sub-steps, the membrane is dried for 48 hours at a temperature of 60° C. in a thermoregulated heat chamber.

According to a first variant of a third embodiment (FIG. 3), the modification step E2 comprises a first modification by plasma-enhanced chemical vapour deposition (PECVD).

The first modification thus comprises:
a sub-step of implementing the layer 2a of the polyurethane in a vacuumed air environment;
a sub-step of introducing a silicon oxide precursor in gaseous form in the vacuumed air environment, such that the precursor is distributed homogenously in the vacuumed air environment;
a sub-step of exposing the layer 2a of polyurethane to the precursor in order to form a layer 5 comprising inorganic silicon oxide.

According to a second variant of the third embodiment, the modification step comprises a second modification by the PECVD technique.

The second modification thus comprises:
a sub-step of implementing the layer 2a of polyurethane in a vacuumed air environment;
a sub-step of introducing dioxygen and a silicon oxide precursor in gaseous form in the vacuumed air environment, such that the dioxygen and the precursor are distributed homogenously in the vacuumed air environment;
a sub-step of exposing the layer 2a of polyurethane to dioxygen and to the precursor in order to form a layer 6 comprising organic silicon oxide.

For the third embodiment, the silicon oxide precursor in gaseous form used by the PECVD technique can include an organosilicon precursor.

As an example, the organosilicon precursor is comprised from among the following precursors: tetramethylsilane (TMS), tetraethyloxisilane, hexamethyldisiloxane, hexamethyldisilazane, tetraethylsilane, tetramethyldisilazane, tetramethyl orthosilicate and tetramethylcyclotetrasiloxane.

According to a variant, the silicon oxide precursor can comprise a hydrocarbon precursor.

As an example, the hydrocarbon precursor corresponds to acetylene.

The production of the second layer or layers 5, 6 of organic and/or inorganic silicon oxides has been implemented using a PECVD device. For example, the PECVD device is composed of a radiofrequency reactor equipped with a generator of electromagnetic waves with a radiofrequency of 13.6 MHz (for example, a Sairem 0-600 W generator) and an aluminium enclosure in the form of a parallelepiped having a rectangular cathode (for example, of dimensions 100 mm×210 mm) connected to the generator and a rectangular anode (for example, of dimensions 100 mm×210 mm) earthed. Once the layer of polyurethane is introduced into the reactor, a primary vacuum, going up to 10⁻⁵ mbar, and then a secondary vacuum, close to 10⁻⁷ mbar, have been created to remove the residual gases which can pollute the process. The layer is deposited on the substrate carrier and the precursor (for example, TMS) is then introduced in gaseous form into the enclosure of the reactor. The introduction and the distribution of the precursor are done homogenously in the whole volume of the reactor.

The two variants of the third embodiment can be combined. Thus, multilayer embodiments can be implemented on one of the surfaces of the layer 2a of polyurethane from a silicon oxide precursor in gaseous form (for example, TMS), by changing at given instants, the ratio between the precursor and dioxygen in the enclosure of the PECVD device. For example, three successive layers 5, 6, 5 are produced as alternating from the organic (SiOₓC_{z}H_{w}) 6 and inorganic (SiOₓ) 5 silicon oxide layers. A first series can be produced by introducing the single precursor into the enclosure, by then introducing a precursor and dioxygen mixture into the enclosure, then by also introducing the single precursor (TMS/TMS+O₂/TMS) into the enclosure. A second series can also be produced by introducing a precursor and dioxygen precursor, by then introducing the single precursor, then by also introducing a precursor and dioxygen mixture (TMS+O₂/TMS/TMS+O₂). In a non-limiting manner, the two series can be produced on at least one of the surfaces of the layer 2a of polyurethane with an exposure time of 8 minutes per layer, under a pressure of 4.4 10⁻² mbar, with a dioxygen flow of 5 sccm (or 5 cm³/minute at standard temperature and pressure conditions) and an excitation power of 100 W.

The different embodiments presented above can be combined together.

Thus, for example, the combination of the third embodiment corresponding to a modification by PECVD technology and the second embodiment corresponding to a modification by jet of sprayed solution makes it possible to increase the properties which are barriers to dioxygen and to water of the layer 2a of polyurethane without altering the properties thereof of it by volume, the biostability thereof, nor the biocompatibility thereof. The permeability to dioxygen of the layer 2a of polyurethane is reduced from 99% and that of water is reduced to 90%.

To evaluate the barrier properties of the flexible barrier membrane 1, several combinations have been produced.

Table A below summarises the results of measurements of permeability to dioxygen and to water of flexible barrier membranes obtained by different embodiments of the method. Table A uses the Barrer as a unit for the permeability coefficient. A value of 1 Barrer corresponds to a value of 1×10⁻¹⁰ Ncm³·cm/(cm²·s·cmHg).

Measuring techniques have been used such as the gravimetric thermal analysis, the differential calorimetric analysis, infrared spectroscopy by Fourier transform in total attenuated reflection mode (IRFT-ATR spectroscopy), scanning electron microscopy, atomic force microscopy, the contact angle, permeability to water and permeability to dioxygen.

The dioxygen flows are measured by considering the passage of dioxygen from an outer surface of the layer 2a of non-modified polyurethane inwards. For example, the measurements of permeability to dry dioxygen are taken using an OX-TRAN Model 2/21 of the company Mocon Inc. It is composed of two measuring cells and of a coulometric detector called COULOX® ultra-low trace to test materials which are great barriers to dioxygen. Each cell is composed of two compartments, called outer chamber and inner chamber, separated by the flexible barrier membrane 1 to be tested. Each cell is scanned by an inert gas consisting of a dinitrogen and dihydrogen mixture (N₂ at 95%) in order to remove any trace of dioxygen. Then, once the signal which is stable and close to zero, dioxygen is applied with a constant flow in the outer chambers of the two cells. Finally, the dioxygen having passed through the flexible barrier membrane 1 is detected in the inner chambers of the cells by the ultra-low trace sensor.

The water flows are measured by considering the passage of the water from an outer surface of the layer 2a of non-modified polyurethane inwards. The measurements of permeability to liquid water have been taken on a permeameter composed of a cell, comprising two compartments called upstream and downstream, between which the flexible barrier membrane 1 to be tested is placed. The sealing is obtained using seals arranged around the active surface of the flexible barrier membrane 1. During the measurement, liquid water is introduced into the upstream compartment, while the downstream compartment is scanned by a dry gas (for example, dinitrogen). Over time, the gas scanning the downstream compartment is enriched with water. A mirrored hygrometer (for example, of General Eastern) detects water molecules having passed through the flexible barrier membrane 1 via the measurement of the dew point temperature T_{R}.

According to a first combination, a multilayer flexible barrier membrane 1 has been produced by a modification of the layers of polyurethane (for example, “Chronoflex® AR-LT” polyurethane) by casting-evaporation of EVA which has undergone a hydrolysis (FIGS. 1 and 2).

For this, an EVA solution (mixture of EVA70 and chloroform) has been cast on a layer 2a of polyurethane. The membrane has then been left at ambient temperature for 3 hours then placed in a heat chamber at 60° C. to remove the residual solvent. This layer of EVA70 is then hydrolysed from a soda-based solution (NaOH 0.8M containing 75% v/v of methanol and 25% of distilled water (“Milli-Q”)). The duration of hydrolysis is 5 hours. The membrane is then washed several times with distilled water, then it is immersed in a 3M hydrochloric acid solution for 15 minutes. The membrane is then rinsed with “Milli-Q” distilled water until a neutral pH is obtained and then dried. The permeability to dioxygen, at 23° C., layers of modified polyurethane has been reduced to 55.3% with respect to a layer of non-modified polyurethane. The permeability to dioxygen is therefore passed from 2.0 Barrer to 0.92 Barrer.

According to a second combination, a multilayer flexible barrier membrane 1 has been produced by a modification by PECVD technology on layers of polyurethane (for example, “Chronoflex® AR-LT” polyurethane) (FIG. 3).

For this, a three-layer deposition from TMS/TMS+O₂/TMS has been carried out on layers 2a of polyurethane with TMS as precursor gas using a radiofrequency reactor equipped with a generator of 13.6 MHz (Sairem 0-600 W) working at a power of 100 W. In the case of the TMS and dioxygen mixture (TMS+O₂), a dioxygen flow of 5 sccm has been used. An exposure time of 8 minutes per layer has been fixed (at a pressure of p=4.4·10⁻² mbar). The modified membranes have presented a decrease of the permeability to dioxygen of 65% with respect to the non-modified membranes. The permeability to dioxygen is therefore passed from 2.0 Barrer to 0.7 Barrer. The modified membranes 1 have presented a decrease of the permeability of water of 5% with respect to the non-modified membranes. The permeability to dioxygen is therefore passed from 7,387 Barrer to 7,000 Barrer at 25° C.

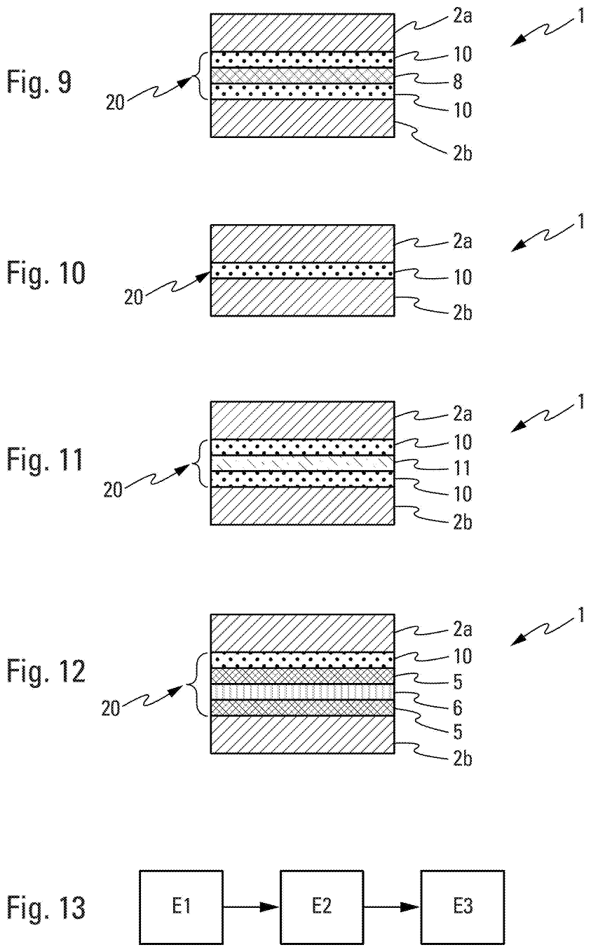

According to a third combination, a multilayer flexible barrier membrane 1 has been produced by a modification by jet of sprayed EVOH and PVDC solution on layers 2a of polyurethane (for example, “Chronoflex® AR-LT” polyurethane) (FIG. 9).

An EVOH32 solution (32% of ethylene ratio) has been sprayed on the surface of the layers 2a of polyurethane using an air brush (for example, a Fengda® BD-134K air brush) with a nozzle and needle diameter of 0.5 mm and a constant working pressure of 4 bar. A drying time of 10 minutes between each layer has been used, then the membranes obtained have been dried for 48 hours at 60° C. The coating consists of 6 layers of EVOH32 10% m/m solution, having a final thickness after drying of around 20 μm. The modified membranes have presented a decrease of the permeability to dioxygen to 99% at 37° C. with respect to the non-modified membranes. The permeability to dioxygen is therefore passed from 3.98 Barrer to 0.04 Barrer. The modified membranes 1 have presented a decrease of the permeability to water of 54% with respect to the non-modified membranes. The permeability to dioxygen is therefore passed from 8,331 Barrer to 3,825 Barrer.

According to a fourth combination, a multilayer flexible barrier membrane 1 has been produced by a modification by jet of PVDC and PIB sprayed solution on layers of polyurethane (for example, “Chronoflex® AR-LT” polyurethane) (FIG. 11).

A PVDC 20% m/m solution has been sprayed on the surface of the layers of polyurethane as described in the third combination. The coating has been constituted of three layers of PVDC 20% m/m solution, having a final thickness after drying of around 20 μm. After drying, this coating has been covered with six layers of PIB 3% m/m solution, having a final thickness after drying of around 12 μm. After drying, a layer of around 6 μm of PVDC 20% m/m has been sprayed so as to ensure adhesion between the PIB and the polyurethane. Finally, this layer has been coated with an 8% polyurethane solution with a final thickness of around 12 μm. The modified membranes 1 have presented a decrease of the permeability to dioxygen to 95% at 37° C. with respect to the non-modified membranes. The permeability to dioxygen is therefore passed from 3.98 Barrer to 0.19 Barrer. The modified membranes 1 have presented a decrease of the permeability to water of 90% with respect to the non-modified membranes. The permeability to dioxygen is therefore passed from 8,331 Barrer to 848 Barrer.

According to a fifth combination, a multilayer flexible barrier membrane 1 has been produced by a modification by PECVD technology and by a modification by jet of PVDC sprayed solution (FIG. 12).

A PVDC 20% m/m solution has been sprayed on the surface of the layers of polyurethane (for example, “Chronoflex® AR-LT” polyurethane) using an air brush (for example, a Fengda® BD-134K air brush), having a nozzle and needle diameter of 0.5 mm and a constant working pressure of 4 bar. The PVDC coating has been constituted of six layers of PVDC 20% m/m solution having a final thickness after drying of around 40 μm. A drying time of 10 minutes between each layer has been used, then the membranes have been dried for 48 hours at 60° C. Subsequently, a three-layer deposition from TMS/TMS+O₂/TMS has been carried out on layers of “Chronoflex® AR-LT” from TMS using a radiofrequency reactor equipped with a generator of 13.6 MHz (for example, a Sairem 0-600 W generator) working at a power of 100 W. A dioxygen flow of 5 sccm has been used. An exposure time of 8 minutes per layer has been fixed (at a pressure of p=4.4·10⁻² mbar). This plasma deposition has then been coated with an 8% polyurethane solution. A drying time of 10 minutes between each layer has been used, then the membranes have been dried for 48 hours at 60° C. The final thickness of the polyurethane coating is around 12 μm. The modified membranes 1 have presented a decrease of the permeability to dioxygen to 88% at 37° C. with respect to the non-modified membranes. The permeability to dioxygen is therefore passed from 3.98 Barrer to 0.48 Barrer. The modified membranes have presented a decrease of the permeability to water of 84% at 37° C. with respect to the non-modified membranes. The permeability to dioxygen is therefore passed from 8,331 Barrer to 1,363 Barrer.

In order to ensure biocompatibility, other combinations have been achieved by depositing an additional layer 2b of polyurethane sandwiching the layers 20 of materials. This deposition of layer 2b of polyurethane can be carried out with the deposition of a polyurethane solution.

TABLE A

| | | Permeability to dioxygen | | | |
|---|---|---|---|---|---|
| | | | | Permeability | |
| | | | | coefficient | |
| | T | Thickness | Flow | ×10¹⁰ cm³/ | |
| Membranes | (° C.) | (μm) | (cm³/m³/day) | cm/s/cmHg | Barrer |
| Polyurethane (PU) | 25 | 332.2 | 447.9 | 2.27 | 2.03 |
| | 27 | 329.4 | 929.0 | 4.66 | 3.98 |
| Modification of the | | | | | |
| PU by casting- evaporation | | | | | |
| Hydrolysed PU/EVA | 23 | 540 | 124.1 | 1.02 | 0.92 |
| Hydrolysed PU/EVA/EVA/PU | 23 | 613 | 159.2 | 1.48 | 1.34 |
| Modification of the | | | | | |
| PU by PECVD technology | | | | | |
| PU/TMS/TMS + O₂/TMS | 25 | 338.3 | 151.6 | 0.78 | 0.70 |
| | 37 | | 959.8 | 4.94 | 4.12 |
| Modification of the | | | | | |
| PU by jet of sprayed solution | | | | | |
| PU/EVOH27 | 37 | 365.3 | 2.87 | 0.01 | 0.02 |
| PU/EVOH32 | 37 | 376.2 | 7.32 | 0.04 | 0.04 |
| PU/EVOH44 | 37 | 427.8 | 10.6 | 0.06 | 0.07 |
| PU/PVDC | 25 | 414.2 | 42.1 | 0.27 | 0.24 |
| | 37 | | | | |
| PU/PIB | 25 | 368.4 | 466.7 | 2.62 | 2.25 |
| PU/PVCD/EVOH32/PVDC/PU | 37 | 386.2 | 26.1 | 0.15 | 0.13 |
| PU/PVDC/PU | 37 | 364.6 | 180.2 | 0.60 | 0.86 |
| PU/PVDC/PIB/PVDC/PU | 37 | 413.6 | 34.6 | 0.22 | 0.19 |
| PU/PVDC/TMS/TMS + O₂/TMS/PU | 37 | 391.6 | 94.4 | 0.56 | 0.48 |

| | Permeability to water | | | |
|---|---|---|---|---|
| | | | Permeability coefficient | |
| | Thickness | Flow × | ×10⁶ cm³/ | |
| Membranes | (μm) | 10⁶ (mmol/cm²/s) | cm/s/cmHg | Barrer |
| Polyurethane (PU) | 352.0 | 2.2 | 0.80 | 7466 |
| | 366.9 | 5.0 | 0.99 | 8331 |
| Modification of the | | | | |
| PU by casting- evaporation | | | | |
| Hydrolysed PU/EVA | | | | |
| Hydrolysed PU/EVA/EVA/PU | | | | |
| Modification of the | | | | |
| PU by PECVD technology | | | | |
| PU/TMS/TMS + O₂/TMS | 318.2 | 2.3 | 0.75 | 7000 |
| | | 5.1 | 0.88 | 7968 |
| Modification of the | | | | |
| PU by jet of sprayed solution | | | | |
| PU/EVOH27 | 355.0 | 2.3 | 0.44 | 3933 |
| PU/EVOH32 | 316.9 | 2.2 | 0.43 | 3825 |
| PU/EVOH44 | 348.0 | 1.9 | 0.37 | 3356 |
| PU/PVDC | 378.3 | 0.6 | 0.23 | 2240 |
| | 372.0 | 1.9 | 0.38 | 3485 |
| PU/PIB | 358.4 | 0.74 | 0.27 | 2418 |
| PU/PVCD/EVOH32/PVDC/PU | 382.0 | 0.88 | 0.18 | 1552 |
| PU/PVDC/PU | 474.6 | 0.72 | 0.18 | 1572 |
| PU/PVDC/PIB/PVDC/PU | 435.2 | 0.41 | 0.10 | 848 |
| PU/PVDC/TMS/TMS + O₂/TMS/PU | 370.0 | 0.78 | 0.16 | 1363 |

1. A flexible barrier membrane, comprising:
at least one first layer of polyurethane, and
at least one second layer of material(s) which are incorporated into the first layer of polyurethane by a modification of at least one surface of the layer or layers of polyurethane, the material or materials of the second layer or layers being comprised from among materials comprising inorganic silicon oxide, organic silicon oxide of chemical formula SiOₓC_{z}H_{w} and a barrier polymer.

2. The membrane according to claim 1, wherein the barrier polymer is comprised from the following polymers: poly(vinyl alcohol-co-ethylene) (EVOH), polyvinylidene chloride (PVDC), polyisobutylene (PIB).

3. The membrane according to claim 1, wherein the layer or layers of material(s) are sandwiched between two layers of polyurethane.

4. A method for producing a flexible barrier membrane, comprising the following steps:
a step (E1) of preparing a layer of polyurethane;
a step (E2) of modifying at least one surface of the layer of polyurethane such that the surface or surfaces of the layer of polyurethane form at least one layer of materials, the material or materials being comprised from among materials comprising a barrier polymer, inorganic silicon oxide and organic silicon oxide of chemical formula SiOₓC_{z}H_{w}.

5. The method according to claim 4, wherein the barrier polymer is comprised from among the following polymers: EVOH, PVDC and PIB.

6. The method according to claim 4, wherein the modification step (E2) comprises a modification by casting-evaporation including the following sub-steps:
a sub-step of casting a poly(vinyl acetate-co-ethylene) (EVA) solution on at least one surface of the layer of polyurethane, the casting sub-step making it possible to deposit a layer of EVA on the layer of polyurethane;
a sub-step of hydrolysing the layer of EVA to obtain a layer of EVOH.

7. The method according to claim 4, wherein the modification step (E2) comprises a modification by jet of sprayed solution including the following sub-steps:
a sub-step of preparing a solution containing at least one barrier polymer;
a sub-step of projection, consisting of projecting said solution on at least one surface of the layer of polyurethane;
a sub-step of drying, to form a layer comprising at least one barrier polymer.

8. The method according to claim 4, wherein the modification step (E2) comprises a first modification by plasma-enhanced chemical vapour deposition including the following sub-steps:
a sub-step of implementing the layer of polyurethane in a vacuumed air environment;
a sub-step of introducing a silicon oxide precursor in gaseous form in the vacuumed air environment, such that the precursor is distributed homogenously in the vacuumed air environment;
a sub-step of exposing the layer of polyurethane to the precursor in order to form a layer comprising inorganic silicon oxide.

9. The according to claim 4, wherein the modification step (E2) comprises a second modification by plasma-enhanced chemical vapour deposition including the following sub-steps:
a sub-step of implementing the layer of polyurethane in a vacuumed air environment;
a sub-step of introducing dioxygen and a silicon oxide precursor in gaseous form in the vacuumed air environment, such that the dioxygen and the precursor is distributed homogenously in the vacuumed air environment;
a sub-step of exposing the layer of polyurethane to dioxygen and to the precursor in order to form a layer comprising organic silicon oxide.

10. The according to claim 8, wherein the silicon oxide precursor comprises an organosilicon precursor in gaseous form.

11. The method according to claim 10, wherein the organosilicon precursor is comprised from among the following precursors: tetramethylsilane (TMS), tetraethyloxisilane, hexamethyldisiloxane, hexamethyldisilazane, tetraethylsilane, tetramethyldisilazane, tetramethyl orthosilicate and tetramethylcyclotetrasiloxane.

12. The method according to claim 8, wherein the silicon oxide precursor comprises a hydrocarbon precursor.

13. The method according to claim 12, wherein the hydrocarbon precursor corresponds to acetylene.

14. The method according to claim 4, further comprising a step (E3) of depositing at least one second layer of polyurethane on the layer or layers of materials such that the layer or layers of materials are sandwiched between the two layers of polyurethane.
